(19) United States
(12) Patent Application Publication
(10) Pub. No.: US 2026/0068098 A1
(43) Pub. Date: Mar. 5, 2026

(54) FLEXIBLE HYDROGEL COLD PLATE FOR THERMAL MANAGEMENT

(71) Applicant: Aivres Systems Inc., Fremont, CA (US)

(72) Inventor: Shin-Chi SHEN, Taipei City (TW)

(21) Appl. No.: 19/382,596

(22) Filed: Nov. 7, 2025

(51) Int. Cl. H05K 7/20; G06F 1/20

(52) U.S. Cl. CPC H05K 7/20463; G06F 1/20; H05K 7/20254; H05K 7/20263; H05K 7/20481; H05K 7/2049; H05K 7/20509; G06F 2200/201

(57) ABSTRACT

A cold plate for cooling memory or PCIe modules includes a metal heat-spreader plate, a thermally conductive gel body beneath the plate, and a flexible polymer encapsulation film that wraps the gel body and presents a device-facing surface contacting the module. Heat flows from the module through the film into the gel and into the plate. In some embodiments the gel is a hydrogel loaded with thermally conductive particles (e.g., boron nitride, alumina, graphene), and the film is a waterproof, extensible material such as TPU that is less compliant than the gel to restrain lateral flow. The plate can be thermally coupled at its longitudinal ends to heat-rejection regions, and may comprise multiple parallel strips aligned over corresponding gel bodies to serve multiple adjacent modules. Retention fixtures may secure the assembly against airflow and vibration.

### TECHNICAL FIELD

The invention relates to thermal management for high-density electronic modules. It relates to a flexible cold-plate structure that employs a thermally conductive hydrogel encapsulated by a high-conductivity, waterproof flexible film to form a compliant heat-transfer interface to electronic modules such as memory modules and PCIe add-in modules. The technology is applicable to high-performance computing, AI training servers, workstations, and data-center platforms demanding an adaptive cooling solution.

### BACKGROUND

Rising bandwidth and power densities in modern computing have pushed both system memory and PCIe add-in modules-such as accelerators, storage controllers, and high-speed I/O cards-into thermal regimes where conventional air cooling no longer suffices. In multi-channel server boards and densely populated backplanes, thermal instability of these modules can throttle performance, shorten component life, and complicate system integration.

Existing cold-plate designs used between adjacent modules generally follow two approaches. Liquid-through plates (as shown in FIG. 1A) route coolant directly through metal bodies positioned between modules, with thermal pads bridging to the chips. Although effective, such plates are heavy, difficult to assemble within tight tolerances, and susceptible to leakage risk. Non-liquid-through plates (as shown in FIG. 1B) instead rely on heat pipes or solid metal spreaders to carry heat to manifold regions at the ends of the module row, where coolant removes it. This approach reduces plumbing complexity but inherits three persistent drawbacks when used with both memory and PCIe cards: rigid metal contact surfaces make it difficult to achieve uniform, low-resistance contact across devices from different vendors with different package heights and local protrusions; increased metal mass complicates installation and service; and device-to-device geometric variation forces bespoke cutouts and pad stacks that do not generalize across module families.

There is therefore a need for a cold-plate architecture that preserves strong heat conduction while remaining mechanically compliant across diverse memory and PCIe module geometries, resists airflow-induced and vibration-induced shifting, and reduces weight.

### SUMMARY

In one general aspect, a cold plate for cooling electronic modules includes a metal heat-spreader plate, a thermally conductive gel body positioned beneath the metal heat-spreader plate with an upper face of the gel body in thermal contact with an underside of the metal heat-spreader plate, and a flexible polymer encapsulation film that wraps the gel body. The encapsulation film defines a device-facing outer surface arranged to contact an electronic module so that heat flows from the module, through the film, into the gel body, and from the gel body into the metal heat-spreader plate.

In some embodiments, the encapsulation film wraps the gel body on a board-facing bottom surface and on four lateral sides while leaving the upper face of the gel body exposed to the metal heat-spreader plate. The gel body may be a hydrogel, optionally loaded with thermally conductive particles such as boron nitride, alumina, graphene, or graphite, and may have a higher thermal conductivity than the encapsulation film to encourage heat flow into the gel. The encapsulation film may be a waterproof, extensible film—such as thermoplastic polyurethane (TPU)—and may include a moisture-barrier layer. The film can be less compliant than the gel body so as to restrain lateral flow of the gel, accommodate insertion of module components, and promote heat transfer into the gel.

The metal heat-spreader plate may be copper, aluminum, or a copper-aluminum laminate, and may be thermally coupled at a longitudinal end region to a heat-rejection region. In some embodiments, at least one heat pipe is thermally coupled at the end region to transfer heat to a coolant manifold or to a finned heat exchanger. The cold plate may further include one or more end-side retention fixtures that restrain movement of the encapsulation film and the gel body under airflow or vibration, for example a U-shaped locking clip; a rigid brace may cooperate with the fixture after module installation to provide additional stabilization. The cold plate can be sandwiched by a pair of electronic modules and, in some layouts, is configured between two adjacent electronic-module sockets. The electronic module may be a memory module or a PCIe add-in card.

In some embodiments, the metal heat-spreader plate comprises multiple elongated heat-spreader strips arranged in parallel, and the thermally conductive gel body comprises a corresponding plurality of gel bodies arranged in parallel beneath the strips, each strip being in direct thermal contact with the upper face of a respective gel body. Opposite longitudinal ends of the strips are thermally coupled to first and second heat-rejection regions located at opposite ends of the cold plate.

In another general aspect, a method of cooling an electronic module includes positioning a cold plate having a metal heat-spreader plate, a thermally conductive gel body disposed beneath the plate, and a flexible polymer encapsulation film wrapping the gel body; bringing a device-facing outer surface of the encapsulation film into contact with the electronic module so that the film transmits heat into the gel body; maintaining the upper face of the gel body in thermal contact with the underside of the metal heat-spreader plate so that heat flows from the gel body into the plate; and rejecting heat from the metal heat-spreader plate at a heat-rejection region located away from the electronic module.

### BRIEF DESCRIPTION OF THE DRAWINGS

FIGS. 1A and 1B illustrate two prior art cold plate designs.

FIG. 2 illustrates a cross-sectional view of the cold plate for heat dissipation, in accordance with some embodiments.

FIG. 3 illustrates a top view of the cold plate for heat dissipation, in accordance with some embodiments.

FIG. 4 illustrates another top view of the cold plate for heat dissipation, in accordance with some embodiments.

FIG. 5 illustrates a perspective view of the cold plate for heat dissipation, in accordance with some embodiments.

FIG. 6A illustrates a front view of the edge of the cold plate with end-side retention fixture, in accordance with some embodiments.

FIG. 6B illustrates a perspective view and a side view of the edge of the cold plate with end-side retention fixture, in accordance with some embodiments.

FIG. 7 illustrates an example method of using the cold plat for heat dissipation, in accordance with some embodiments.

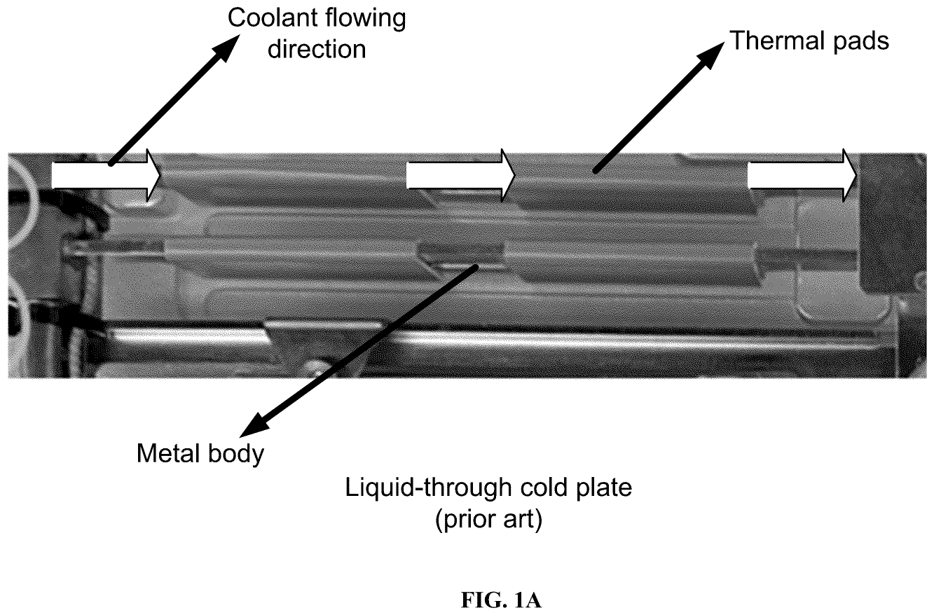

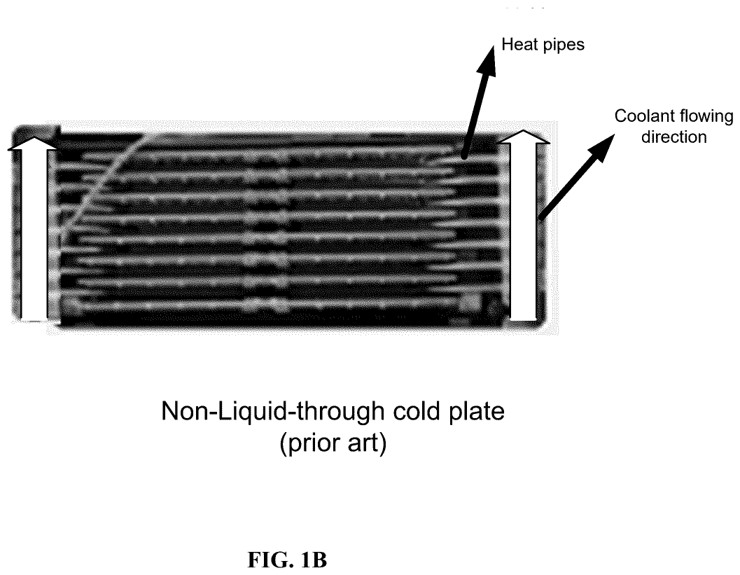

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

To address the issues in existing cold-plate designs, this disclosure employs a thermally conductive gel body (optionally a hydrogel loaded with thermally conductive particles such as boron nitride, alumina, or graphene) wrapped by a flexible polymer encapsulation film on all sides except the upper face that is in thermal contact with a metal heat-spreader plate. The gel body provides a soft, conformal, low-resistance interface to the electronic module through the film's device-facing outer surface, the encapsulation film stabilizes the gel body and inhibits drying of the gel body while transmitting heat into it, and the metal heat-spreader plate conducts the heat along its length to one or more heat-rejection regions positioned away from the module. In addition, end-side retention fixtures, such as a U-shaped locking clip and an optional rigid brace, may be used to restrain movement of the encapsulation film and the gel body under fan airflow and vibration to maintain balanced heat transfer across installed modules.

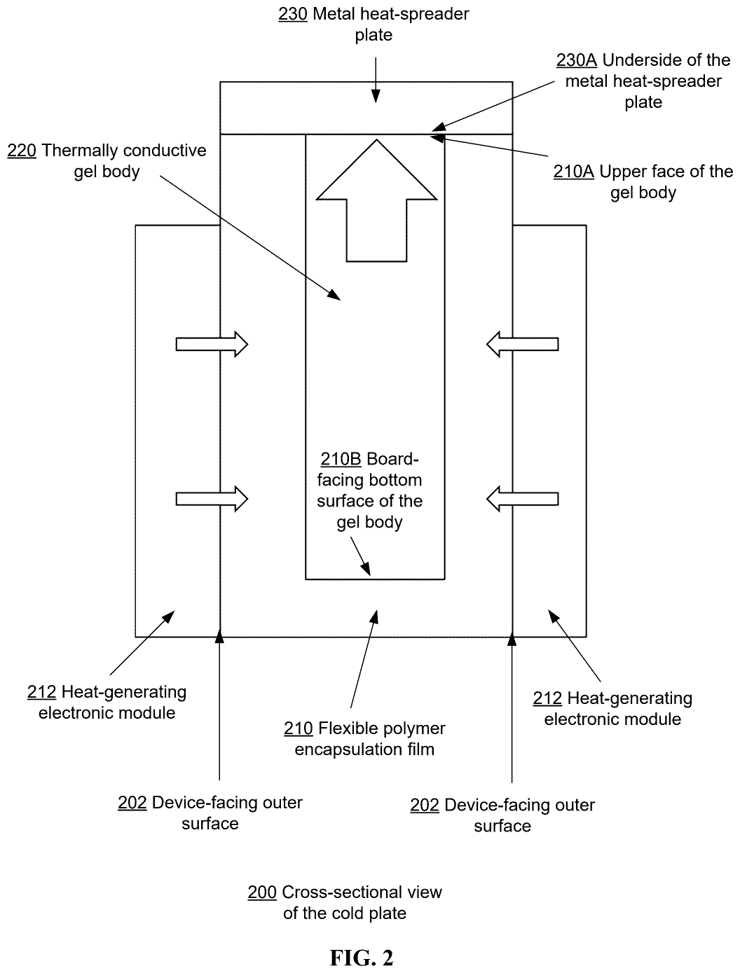

FIG. 2 illustrates a cross-sectional view 200 of the cold plate for heat dissipation, in accordance with some embodiments. A flexible polymer encapsulation film (also referred to as “encapsulation film” or “film”) 210 wraps a thermally conductive gel body (also referred to as “gel body”) 220 while presenting device-facing outer surfaces 202 that contact heat-generating electronic modules 212 disposed on opposite sides. The gel body 220 is positioned beneath a metal heat-spreader plate 230 such that an upper face 210A of the gel body 220 is in direct thermal contact with an underside 230A of the metal heat-spreader plate 230. During operation, heat flows (as shown using the arrows) from the electronic modules 212 through the encapsulation film 210 into the gel body 220 and from the gel body 220 into the metal heat-spreader plate 230, where heat is conducted along the metal heat-spreader plate 230 toward a heat-rejection region or element.

In the configuration of FIG. 2, the flexible polymer encapsulation film 210 is the interface that directly contacts components on the heat-generating electronic modules 212 (e.g., memory packages or PCIe devices). The encapsulation film 210 mechanically wraps the thermally conductive gel body 220 and prevents moisture loss of the gel body 220, while the gel body 220 remains highly compliant. This creates a double-layer compliance, in which the film 210 yields locally to protrusions and height/thickness variation of the electronic device (here, “height” refers to the elevation of the electronic device surface above the board or socket datum, including package thickness plus any standoff from solder, adhesives, labels, coatings, or board warp), and the gel body 220 further deforms to preserve real contact area. This way, heat flows through the film 210 into the gel body 220 and then into the metal heat-spreader plate 230 with lower interface resistance (from increased real contact area and the elimination of microgaps/voids at both interfaces) and without excessive assembly force (because the compliant gel body 220 and flexible film 210 conform under modest clamping pressure, avoiding high preload that could damage components or warp the board).

In some embodiments, the encapsulation film 210 wraps the gel body 220 on a board-facing bottom surface 210B and on four lateral sides while leaving the upper face of the gel body 220 exposed to the metal heat-spreader plate 230. The encapsulation film 210 may comprise a waterproof, extensible film configured to transmit heat into the gel body 220 and, in some embodiments, may comprise thermoplastic polyurethane (TPU). The encapsulation film 210 may be less compliant than the gel body 220 so as to restrain lateral flow of the gel body 220 (the gel body 220 is constrained within the flexible polymer encapsulation film 210, so the gel body 220's lateral flow is restrained), accommodate insertion of components of the electronic modules 212, and promote heat transfer into the gel body 220. In some embodiments, the encapsulation film 210 further includes a moisture-barrier layer configured to inhibit drying of the gel body 220 during service.

The thermally conductive gel body 220 may comprise a hydrogel. In some embodiments, the hydrogel includes thermally conductive particles selected from boron nitride, alumina, graphene, graphite, or combinations thereof, and the hydrogel has a thermal conductivity greater than that of the encapsulation film 210 to encourage heat flow into the gel body 220. The metal heat-spreader plate 230 may comprise copper, aluminum, or a copper-aluminum laminate.

As depicted, the cold plate (more specifically, the encapsulation film 210 and the gel body 220) is configured to be sandwiched by a pair of electronic modules 212. In some embodiments, each electronic module 212 comprises a memory module (e.g., a DIMM) or a PCIe add-in card. Other implementations may position only one electronic module 212 against the device-facing outer surface of the encapsulation film 210 while an opposing side of the cold plate interfaces with a chassis wall or another thermal structure.

Although a filled TPU pad alone could be used in some embodiments, the gel-plus-film architecture offers multiple advantages. First, thermal conduction: the gel body 220 can be loaded with a higher fraction of thermally conductive particles (e.g., BN, alumina, graphene) than is practical in a standalone encapsulation film 210 (e.g., TPU), achieving lower bulk thermal resistance at useful thicknesses.

Second, serviceability: in some embodiments, the gel body 220 is implemented as a replaceable insert received within the encapsulation film 210, so refreshing or swapping the gel can be done without replacing the encapsulation film 210 or the metal heat-spreader plate 230. This reduces cost, preserves the moisture-barrier and mechanical properties of the film 210, and allows selecting different gel formulations (e.g., with different filler loadings) for different thermal targets.

Third, mechanical stability: the encapsulation film 210 provides tear strength, moisture barrier, and lateral flow restraint, avoiding gel creep during insertion and vibration, while the gel body 220 supplies damping and low compression set under repeated cycling. Thus, the composite structure attains lower total thermal resistance and broader geometric tolerance than a single TPU layer, while maintaining robustness and service life. In some embodiments, a single material (e.g., a highly filled TPU) may be substituted, but with generally higher thermal/interface resistance or reduced compliance compared to the gel-plus-film configuration.

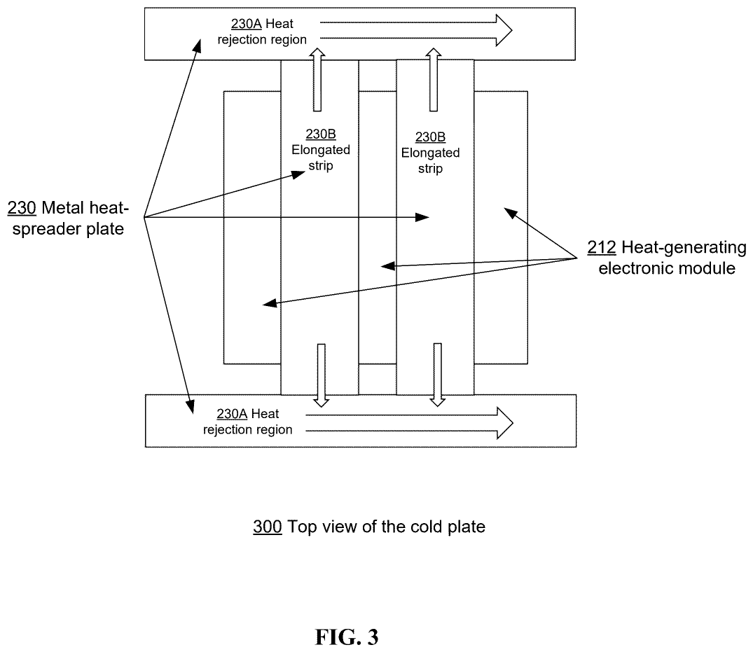

FIG. 3 illustrates a top view 300 of the cold plate for heat dissipation, in accordance with some embodiments. In the embodiment shown, the metal heat-spreader plate 230 first includes a plurality of elongated heat-spreader strips arranged in substantially parallel with adjacent heat-generating electronic modules 212. Each strip of the metal heat-spreader plate 230 overlies the flexible polymer encapsulation film 210 and is in direct thermal contact with an upper face of the thermally conductive gel body 220 beneath it, so that heat generated by the electronic modules 212 is absorbed along the lengths of the strips. The metal heat-spreader plate 230 further includes opposite longitudinal end heat-rejection regions located at ends of the array of elongated heat-spreader strips; the arrows in FIG. 3 indicate the principal heat-flow path from the electronic modules 212 into the strips and then longitudinally along the strips toward the end heat-rejection regions. In some embodiments, the end heat-rejection regions may be considered external to the metal heat-spreader plate 230. The end heat-rejection regions may be positioned away from the electronic modules 212 and may include, or be in thermal contact with, a heat exchanger, a heat sink, or another remote exchanger to remove the heat conducted along the strips.

In some embodiments, the heat-spreader strips of the metal heat-spreader plate 230 may vary in width or thickness along their lengths to match heat density of the adjacent heat-generating electronic modules 212. Wider or thicker portions may be aligned with known hot-zones of the modules 212 so that longitudinal conduction into the end heat-rejection regions is increased without adding mass where it is not needed.

Relative to cold plates that rely on rigid metal blocks and thick pads, the architecture in FIG. 3 reduces total thermal resistance by combining a high-conductivity path along the metal heat-spreader plate 230 with a compliant, low-resistance interface formed by the encapsulation film 210 backed by the gel body 220. In one embodiment, no coolant channels is configured to traverse the area directly above the electronic modules 212, thus the design reduces mass, eliminates local leak paths, and relaxes board-level keep-out and electrical-clearance constraints. The direct contact between the gel body 220 and the metal heat-spreader plate 230 minimizes interface losses, while the strip-and-manifold topology conducts heat longitudinally to the end heat-rejection regions where larger exchangers can be placed. The result is improved temperature uniformity across multiple electronic modules 212 under manufacturing tolerances and vibration, with easier serviceability via a replaceable gel body 220 and durable moisture retention provided by the encapsulation film 210.

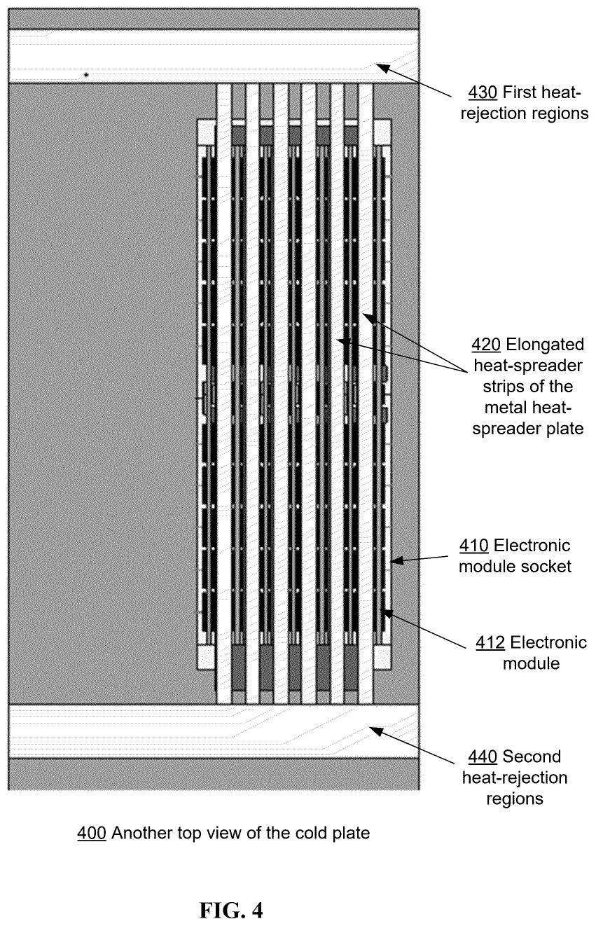

FIG. 4 illustrates another top view 400 of the cold plate for heat dissipation, in accordance with some embodiments. As shown, an electronic module 412 (memory card or PCI card) is received in each electronic module socket 410, and a metal heat-spreader plate is realized as multiple elongated heat-spreader strips (also referred to as “elongated strip(s)” or “strip(s)”) 420 that run generally parallel to the electronic module 412. Each elongated strip 420 overlies the flexible polymer encapsulation film (blocked by the strip 420 from the top view) and is in direct thermal contact with an upper face of the thermally conductive gel body beneath it (blocked by the strip 420 from the top view), so heat generated by the modules 412 is absorbed along the lengths of the strips 420. Opposite ends of the strip array are thermally coupled to a first heat-rejection region 430 and a second heat-rejection region 440, respectively, positioned away from the modules 412 so that heat conducted along the strips 420 is delivered to these end regions for removal.

In some embodiments, the first heat-rejection region 430 and the second heat-rejection region 440 may include, or be in thermal contact with, a manifold block, a chassis heat sink, or another remote exchanger. In other embodiments, one or both the heat-rejection regions 430 and 440 may couple to heat pipes that route heat to a coolant manifold or a finned heat exchanger. The elongated strip topology shown in FIG. 4 permits efficient longitudinal conduction to the first heat-rejection region 430 and the second heat-rejection region 440 while keeping the area immediately above the modules 412 (in some embodiments, free of coolant channels, thereby reducing weight and leak risk and easing board-level keep-out constraints).

In some embodiments, the spacing between adjacent elongated heat-spreader strips 420 forms open slits that permit chassis fan airflow to pass through the strip array. In comparison to using a solid plate that would cover the entire span of the underlying flexible polymer encapsulation films and thermally conductive gel bodies, these open slits reduce flow impedance and promote convective heat transfer over surfaces of the strips 420, thereby further enhancing overall heat-dissipation efficiency. The through-flow can also sweep along tops of the electronic modules 412 seated in the electronic module socket 410, augmenting cooling while heat is simultaneously conducted longitudinally to the first heat-rejection region 430 and the second heat-rejection region 440.

In the layout of FIG. 4, the cold plate is configured between two adjacent electronic module sockets 410 on the printed circuit board such that the device-facing outer surfaces of the flexible polymer encapsulation film contact electronic modules 412 seated in the opposed sockets 410. In this arrangement, the cold plate occupies the interstitial space between the neighboring sockets 410 and simultaneously serves the facing sides of the two electronic modules 412.

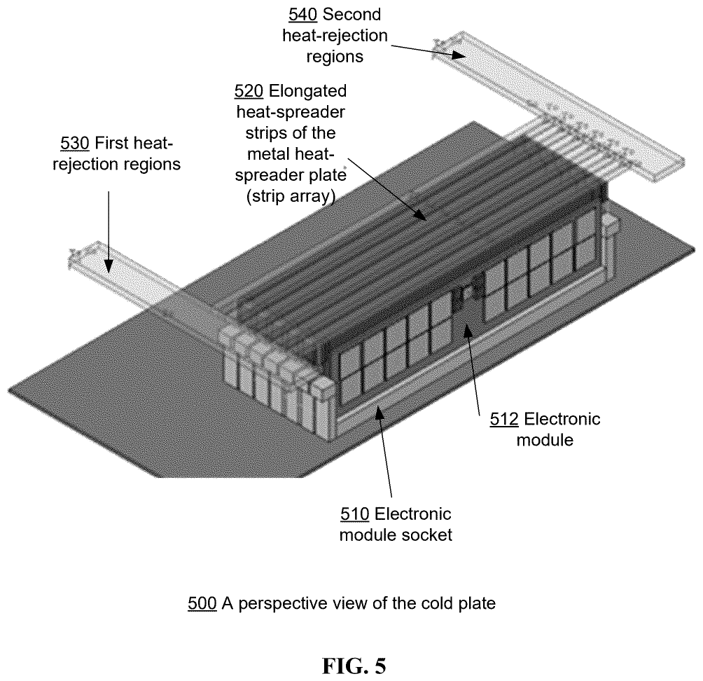

FIG. 5 illustrates a perspective view 500 of the cold plate for heat dissipation, in accordance with some embodiments. In this view the relationship between the elongated heat-spreader strips 520 of the metal heat-spreader plate and the board-level hardware is visible. Each electronic module 512 is seated in an electronic module socket 510, and the strip array 520 lies above the flexible polymer encapsulation film and the thermally conductive gel bodies. The perspective view makes clear that opposite longitudinal ends of the strip array 520 are thermally coupled to a first heat-rejection regions 530 and a second heat-rejection regions 540. These end regions are positioned away from the electronic modules 512 and provide the interfaces for removing heat conducted along the strips.

This perspective view shows how the first heat-rejection region 530 and the second heat-rejection region 540 can be implemented as discrete bodies that may sit at different elevations or even outside the footprint of the socket 510, allowing plumbing, heat pipes, or manifold blocks to be attached with adequate mechanical clearance. This geometry shows how the strip array 520 forms a low-profile bridge over the modules 512 while delivering heat longitudinally to the end regions, leaving the area above the modules free of liquid channels and preserving keep-out for latches and connectors on the socket 510.

In some embodiments, one or both end regions 530, 540 are realized as clamp-on bars or headers bonded to the ends of the strips 520; in other embodiments, the end regions 530, 540 receive one or more heat pipes that route heat to a coolant manifold or to a finned heat exchanger mounted on the chassis. The perspective view also illustrates the open slits between adjacent strips 520, which may align with chassis fan flow to promote convective cooling in addition to conduction along the strips.

The perspective view further shows that the cold plate can be assembled and serviced as a single module spanning multiple electronic modules 512. In some embodiments, the thermally conductive gel body is configured as a replaceable insert retained by the flexible polymer encapsulation film under the strip array 520, enabling gel refresh without disturbing the end regions 530, 540 or the electronic module socket 510.

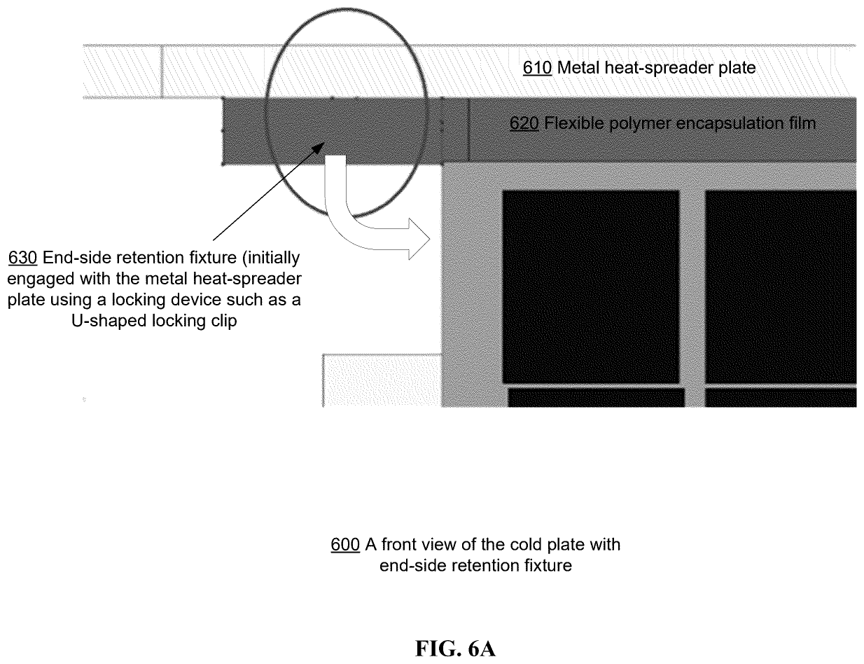

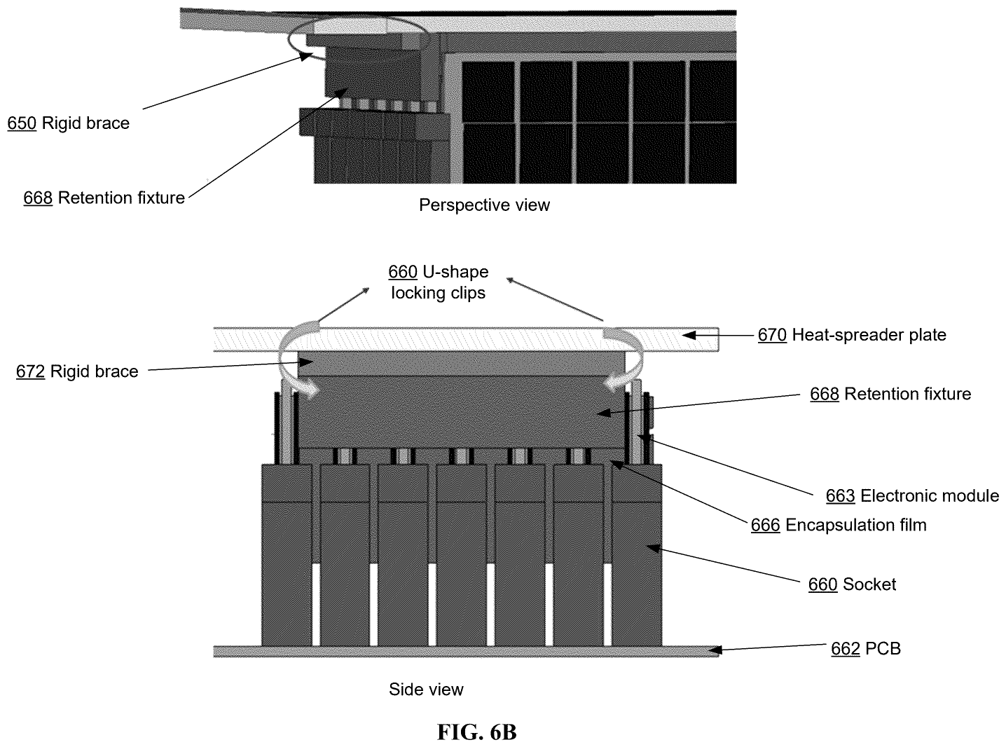

FIG. 6A illustrates a front view 600 of the edge of the cold plate with an end-side retention fixture, in accordance with some embodiments. A metal heat-spreader plate 610 is disposed above a flexible polymer encapsulation film 620. The film 620 overlies and retains a thermally conductive gel body 220 (not separately shown in this view). An electronic module is depicted adjacent the film 620, with discrete components on the module shown schematically as dark blocks. In operation, the device-facing outer surface of the film 620 contacts the electronic-module components so that heat is transferred through the film 620 into the gel body 220 and then into the metal heat-spreader plate 610.

In some embodiments, an end-side retention fixture 630 is positioned at the edge of the cold plate to restrain movement of the flexible polymer encapsulation film 620 and the gel body 220 under airflow or vibration. Because both the encapsulation film 620 and the gel body 220 are compliant, chassis-fan airflow can otherwise cause local shifting that leads to uneven thermal contact; the fixture 630 mechanically locks the edge of the film 620 and the gel body 220 in place to maintain uniform heat transfer.

In some embodiments, the retention fixture 630 is initially oriented substantially horizontal during installation. The fixture 630 may be temporarily engaged with the metal heat-spreader plate 610 using a locking device such as a U-shaped locking clip. After the electronic module is inserted and the cold plate positioned, the fixture 630 is bent or rotated downward to a locked position that clamps the film 620 and the gel body 220 at the edge of the assembly. In other embodiments, the fixture 630 includes a living hinge, a scored bend line, or a discrete hinge pin that facilitates the transition from the horizontal pre-install orientation to the locked orientation.

Although FIG. 6A shows a single edge, the opposite edge of the cold plate may include a similar retention fixture 630. In some embodiments, a single elongated fixture spans multiple cold plates and associated electronic modules to tie the array together; in other embodiments, individual fixtures are provided for each cold plate. The fixture 630 may be formed of metal or a rigid polymer, and may include compliant inserts or stops to set clamping force while limiting film creep under sustained airflow.

FIG. 6B illustrates a perspective view and a side view of the edge of the cold plate with an end-side retention fixture, in accordance with some embodiments. In both views a metal heat-spreader plate 670 is positioned above a flexible polymer encapsulation film 666 that retains the underlying thermally conductive gel body (not separately labeled here). An electronic module 663 is received in a socket mounted on a printed circuit board (PCB) 662. In the perspective view, the end-side retention fixture 668 is shown at the margin of the cold plate, and a rigid brace 650 overlies the end-side retention fixture 668 to provide an additional layer of stabilization at the edge.

The side view highlights the installed condition. Unlike FIG. 6A, where the retention fixture was oriented substantially horizontal prior to locking, in FIG. 6B the retention fixture 668 is bent downward to clamp the edge of the encapsulation film 666 (and the gel body retained within it) against the structure beneath the heat-spreader plate 670. In some embodiments, U-shaped locking clips 660 engage the heat-spreader plate 670 to hold the retention fixture 668 in the bent, locked orientation during service.

In some embodiments, a rigid brace 672 may be applied to cooperate with the bent retention fixture 668. The rigid brace 672 spans along the edge and reacts to airflow-induced and vibration-induced loads, limiting flutter of the encapsulation film 666 and creep of the gel body. In some embodiments the rigid brace 650/672 is metal or a rigid polymer and includes stops or a hinge feature that sets clamping force while avoiding over-compression of the encapsulation film 666. The combination of the bent retention fixture 668, the U-shaped locking clips 660, and the rigid brace 650/672 secures the edge of the cold plate and maintains uniform thermal contact during operation.

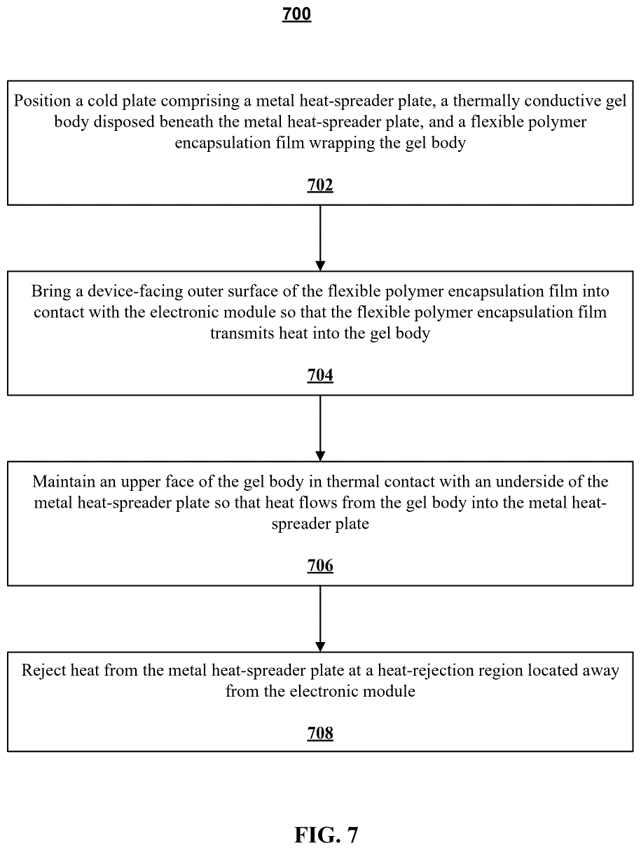

FIG. 7 illustrates an example method 700 of using the cold plate for heat dissipation, in accordance with some embodiments. At step 702, a cold plate is positioned that includes a metal heat-spreader plate, a thermally conductive gel body disposed beneath the metal heat-spreader plate, and a flexible polymer encapsulation film wrapping the gel body. At step 704, a device-facing outer surface of the flexible polymer encapsulation film is brought into contact with an electronic module so that the encapsulation film transmits heat into the gel body. At step 706, an upper face of the gel body is maintained in thermal contact with an underside of the metal heat-spreader plate so that heat flows from the gel body into the metal heat-spreader plate. At step 708, heat is rejected from the metal heat-spreader plate at a heat-rejection region located away from the electronic module.

In some embodiments, the positioning of step 702 includes placing a metal heat-spreader plate that comprises a plurality of elongated heat-spreader strips arranged in parallel, and providing a thermally conductive gel body that comprises a corresponding plurality of gel bodies arranged in parallel beneath the elongated heat-spreader strips. In such embodiments, each of the plurality of gel bodies is encapsulated by a corresponding flexible polymer encapsulation film, and each heat-spreader strip is in direct thermal contact with the upper face of a respective one of the gel bodies so that parallel heat-transfer paths are established.

In some embodiments, the heat rejecting of step 708 includes thermally coupling opposite longitudinal ends of the plurality of elongated heat-spreader strips to first and second heat-rejection regions located at opposite ends of the cold plate. The heat absorbed from the electronic module through the encapsulation film and the gel bodies is thereby conducted longitudinally along the strips to the first and second heat-rejection regions, which may include, or be in thermal contact with, a manifold block, a heat sink, a coolant manifold, a finned heat exchanger, or another remote exchanger positioned away from the electronic module.

The various features and processes described above may be used independently of one another or may be combined in various ways. All possible combinations and sub-combinations are intended to fall within the scope of this disclosure. In addition, certain method or process blocks may be omitted in some implementations. The methods and processes described herein are also not limited to any particular sequence, and the blocks or states relating thereto can be performed in other sequences that are appropriate. For example, described blocks or states may be performed in an order other than that specifically disclosed, or multiple blocks or states may be combined in a single block or state. The example blocks or states may be performed in serial, in parallel, or in some other manner. Blocks or states may be added to or removed from the disclosed example embodiments. The exemplary systems and components described herein may be configured differently than described. For example, elements may be added to, removed from, or rearranged compared to the disclosed example embodiments.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the subject matter has been described with reference to specific example embodiments, various modifications and changes may be made to these embodiments without departing from the broader scope of embodiments of the present disclosure. Such embodiments of the subject matter may be referred to herein, individually or collectively, by the term “invention” merely for convenience and without intending to voluntarily limit the scope of this application to any single disclosure or concept if more than one is, in fact, disclosed.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

Any process descriptions, elements, or blocks in the flow diagrams described herein and/or depicted in the attached figures should be understood as potentially representing modules, segments, or portions of code which include one or more executable instructions for implementing specific logical functions or steps in the process. Alternate implementations are included within the scope of the embodiments described herein in which elements or functions may be deleted, executed out of order from that shown or discussed, including substantially concurrently or in reverse order, depending on the functionality involved, as would be understood by those skilled in the art.

As used herein, “or” is inclusive and not exclusive, unless expressly indicated otherwise or indicated otherwise by context. Therefore, herein, “A, B, or C” means “A, B, C, A and B, A and C, B and C, or A, B, and C,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context. Moreover, plural instances may be provided for resources, operations, or structures described herein as a single instance. Additionally, boundaries between various resources, operations, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

The term “include” or “comprise” is used to indicate the existence of the subsequently declared features, but it does not exclude the addition of other features. Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

What is claimed is:

1. A cold plate, comprising:
a metal heat-spreader plate;
a thermally conductive gel body positioned beneath the metal heat-spreader plate with an upper face of the gel body in thermal contact with an underside of the metal heat-spreader plate; and
a flexible polymer encapsulation film wrapping the gel body, the flexible polymer encapsulation film defining a device-facing outer surface arranged to contact an electronic module so that heat flows from the electronic module through the flexible polymer encapsulation film into the gel body and from the gel body into the metal heat-spreader plate.

2. The cold plate of claim 1, wherein the flexible polymer encapsulation film wraps the gel body on a board-facing bottom surface and on four lateral sides while leaving the upper face of the gel body exposed to the metal heat-spreader plate.

3. The cold plate of claim 1, wherein the thermally conductive gel body comprises a hydrogel.

4. The cold plate of claim 3, wherein the hydrogel comprises thermally conductive particles selected from boron nitride, alumina, graphene, graphite, or combinations thereof.

5. The cold plate of claim 3, wherein the hydrogel has a thermal conductivity greater than a thermal conductivity of the flexible polymer encapsulation film.

6. The cold plate of claim 1, wherein the flexible polymer encapsulation film comprises a waterproof, extensible film configured to transmit heat into the gel body.

7. The cold plate of claim 6, wherein the flexible polymer encapsulation film comprises thermoplastic polyurethane (TPU).

8. The cold plate of claim 1, wherein the flexible polymer encapsulation film is less compliant than the gel body so as to restrain lateral flow of the gel body, accommodate insertion of components of the electronic module, and transmit heat into the gel body.

9. The cold plate of claim 1, wherein the metal heat-spreader plate is thermally coupled at a longitudinal end region to a heat-rejection region.

10. The cold plate of claim 9, further comprising at least one heat pipe thermally coupled to the metal heat-spreader plate at the longitudinal end region to transfer heat to a coolant manifold or to a finned heat exchanger.

11. The cold plate of claim 1, further comprising at least one end-side retention fixture configured to restrain movement of the flexible polymer encapsulation film and the gel body under airflow or vibration.

12. The cold plate of claim 11, wherein the end-side retention fixture comprises a U-shaped locking clip engageable with the metal heat-spreader plate.

13. The cold plate of claim 12, further comprising a rigid brace configured to cooperate with the end-side retention fixture after installation of the electronic module.

14. The cold plate of claim 1, wherein the metal heat-spreader plate comprises copper, aluminum, or a copper-aluminum laminate.

15. The cold plate of claim 1, wherein the cold plate is configured to be sandwiched by a pair of electronic modules.

16. The cold plate of claim 1, wherein the cold plate is configured between two adjacent electronic module sockets.

17. The cold plate of claim 1, wherein the electronic module comprises a computer memory or a PCIe add-in card.

18. The cold plate of claim 1, wherein the flexible polymer encapsulation film comprises a moisture-barrier layer configured to inhibit drying of the gel body during service.

19. The cold plate of claim 1, wherein the metal heat-spreader plate comprises a plurality of elongated heat-spreader strips arranged in parallel, and
the thermally conductive gel body comprises a corresponding plurality of gel bodies arranged in parallel beneath the plurality of elongated heat-spreader strips, and each of the plurality of gel bodies being encapsulated by a corresponding flexible polymer encapsulation film, and
each heat-spreader strip being in direct thermal contact with the upper face of a respective one of the gel bodies,
wherein opposite longitudinal ends of the plurality of elongated heat-spreader strips are thermally coupled to first and second heat-rejection regions located at opposite ends of the cold plate.

20. A method of cooling an electronic module on a circuit board, comprising:
positioning a cold plate comprising a metal heat-spreader plate, a thermally conductive gel body disposed beneath the metal heat-spreader plate, and a flexible polymer encapsulation film wrapping the gel body;
bringing a device-facing outer surface of the flexible polymer encapsulation film into contact with the electronic module so that the flexible polymer encapsulation film transmits heat into the gel body;
maintaining an upper face of the gel body in thermal contact with an underside of the metal heat-spreader plate so that heat flows from the gel body into the metal heat-spreader plate; and
rejecting heat from the metal heat-spreader plate at a heat-rejection region located away from the electronic module.
